(19) United States
(12) Patent Application Publication
(10) Pub. No.: US 2013/0108886 A1
(43) Pub. Date: May 2, 2013

(54) METAL COMPONENT, METHOD FOR PRODUCING A METAL COMPONENT, AND FITTING, PIECE OF FURNITURE AND HOUSEHOLD APPLIANCE

(71) Applicants: Peter Jährling, Bunde (DE); Daniel Rehage, Bielefeld (DE); Uwe Sobolewski, Bunde (DE); Lars Schrubke, Kirchlengern (DE); Willi Grigat, Gutersloh (DE); Arthus Krause, Lubbecke (DE); Björn Gebhardt, Oelde (DE)

(72) Inventors: Peter Jährling, Bunde (DE); Daniel Rehage, Bielefeld (DE); Uwe Sobolewski, Bunde (DE); Lars Schrubke, Kirchlengern (DE); Willi Grigat, Gutersloh (DE); Arthus Krause, Lubbecke (DE); Björn Gebhardt, Oelde (DE)

(73) Assignee: PAUL HETTICH GMBH & CO. KG, Kirchlengern (DE)

(21) Appl. No.: 13/696,920

(22) PCT Filed: May 11, 2011
(86) PCT No.: PCT/EP2011/057599

§ 371 Date: Jan. 8, 2013

(30) Foreign Application Priority Data
May 12, 2010 (DE) 10 2010 016 911.0

(51) Int. Cl. A47B 88/04; B32B 3/10; B23K 9/00; C23C 4/00; C25D 7/02; C23C 14/34; B32B 15/04; C23C 16/00

(52) U.S. Cl. CPC A47B 88/04; B32B 15/04; B32B 3/10; B32B 15/043; C23C 16/00; C23C 4/00; C25D 7/02; C23C 14/34; B23K 9/00
USPC 428/601; 428/457; 428/209; 428/615; 428/450; 427/248.1; 427/250; 427/446; 205/316; 205/118; 219/136

(57) ABSTRACT

A metal component for one or more of a fitting, a piece of furniture and a household appliance. The metal component includes a coating, at least in sections, the coating including one of a hardness-containing composite material and a ceramic-metal composite material.

### CROSS-REFERENCE TO RELATED APPLICATION

This application is a national stage of International Application PCT/EP2011/057599, filed May 11, 2011, and claims benefit of and priority to German Patent Application No. 10 2010 016 911.0, filed May 12, 2010, the content of which Applications are incorporated by reference herein.

### BACKGROUND AND SUMMARY

The present disclosure relates to a metal component, especially for a fitting, a piece of furniture and/or a domestic appliance. The present disclosure also relates to a method for producing that metal component, and to a fitting, a piece of furniture and/or a household appliance that comprises that metal component arranged in or on the fitting, piece of furniture or household appliance.

Untreated special steels or special steels with organic-inorganic hybrid polymer coatings were used until now in the field of fittings, as published, for example, in DE 10 2008 059 908.5.

DE 103 40 482 A1 discloses a telescopic rail, comprising a coating made of a hard material. This coating can be provided—with, among other things, coatings made of hard materials such as carbides, nitrides, carbonitrides, and the coating can be applied to the tracks of the pull-out guide. These coatings are used for reducing friction on the sliding surfaces. A number of hard-material coatings have microporosity, so that they are only corrosion-resistant for a short period of time.

Embodiments of the present disclosure provide for a metal component which is corrosion-resistant and scratch-proof.

The present disclosure thus relates to a metal component for one or more of a fitting, a piece of furniture and a household appliance. The metal component includes a coating, at least in sections. The coating includes one of a hardness-containing composite material and a ceramic-metal composite material. The present disclosure also relates to a method of producing the metal component. The method steps includes providing the metal component, and applying the coating, at least in sections by one of gas-phase deposition, chemical deposition, electrochemical deposition, thermal spraying, and welding.

Thus, a metal component, especially for a fitting, a piece of furniture and/or a household appliance, comprises a coating at least in some sections. The coating contains a hard-material-containing composite or a ceramic-metal composite.

The metal component can be used, for example, as a fitting in any kind of furniture or household appliances, for example, whiteware products such as microwave devices, steam cookers and other heating devices for heating food, for example, with pyrolysis cleaning, freezers, washing machines, dishwashers, tumble dryers and the like.

Since the hard-material-containing composite coating of the present disclosure is corrosion-proof and scratch-proof, the use of special steel in fittings can be avoided. This leads to a considerable price advantage and also to an advantage in transport as a result of lower mass.

Embodiments of the present disclosure are discussed herein and in the appended claims.

It is advantageous, according to embodiments of the present disclosure, if the coating has a Vickers hardness of more than 300 HV10, where 300=hardness value, HV=method and 10=testing force in kilopond. According to the present disclosure, the Vickers hardness may be between 500 to 1000 HV10 or may be between 600 and 750 HV10. These hardnesses advantageously ensure increased scratch resistance of the coating.

According to the present disclosure, it is advantageous to use the metal component in the area of ovens for baking, for example, as a pull-out guide or foodstuff rack, when the melting point of the coating is more than 300° C., or between 400 and 900° C., or between 500 and 700° C. This corresponds to the temperature which is reached with a conventional oven. If the coating has a melting point over 500° C., the metal component of the present disclosure can also be used, for example, as a fitting in form of a pull-out guide or side gratings in ovens with pyrolysis cleaning.

It is advantageous, according to the present disclosure, if the composite has a mass fraction of over 50% of a metal and/or a ceramic material. The ductility of the metal matrix and the flexibility and deformability of the metal can, therefore, be especially utilized in a metal-based coating. In the case of a ceramic coating, the brittleness of the coating can be optimized, advantageously, according to the present disclosure, by microstructure adjustment for example.

Hard materials chosen from a group consisting of carbides, nitrides, borides and silicides are, according to the present disclosure, advantageous for increasing scratch resistance. The effect of scratch resistance will, advantageously, be amplified in particular by carbides, nitrides, borides and silicides of high-melting transition metals such as titanium, tantalum, tungsten and molybdenum, including their mixed crystals and complex compounds.

Furthermore, corundum, fluorapatite or mixtures thereof can, according to the present disclosure, be used as hard materials. These hard materials occur naturally. Fluorapatite, like corundum, represents no health risk and can be used in fittings which are used in the food area such as ovens or refrigerators.

The friction of mutually moving components of a fitting such as a pull-out guide or a hinge, will be reduced by a lubricant. The lubricant can, according to the present disclosure, advantageously be introduced into the composite, so that it is not removed by frequent use but remains on the surface. This applies especially to solid lubricants such as molybdenum sulfide, PTFE, PFA, graphite or alpha-boron nitride.

The coating, in accordance with the present disclosure, meets the requirements of the Regulation (EC) No. 1935/2004 of the European Parliament and the Council of 27 Oct. 2004 on materials and articles intended to come into contact with food and repealing Directives 80/590/EEC and 89/109/EEC.

In accordance with the present disclosure, a method for producing a metal component comprises the step of providing the metal component according to the present disclosure and applying, at least in sections, the hardness containing composite material or the ceramic-metal composite material. The application occurs by vapor-phase, or gas-phase, deposition, chemical, or chemical-vapor deposition, electrochemical deposition, thermal spraying or deposition welding.

Other aspects of the present disclosure will become apparent from the following descriptions when considered in conjunction with the accompanying drawings.

### BRIEF DESCRIPTION OF THE DRAWINGS

FIGS. 1 to 3 show several views of an embodiment of a metal component, in accordance with the present disclosure, which metal component is arranged as a fitting in the form of a pull-out guide.

### DETAILED DESCRIPTION

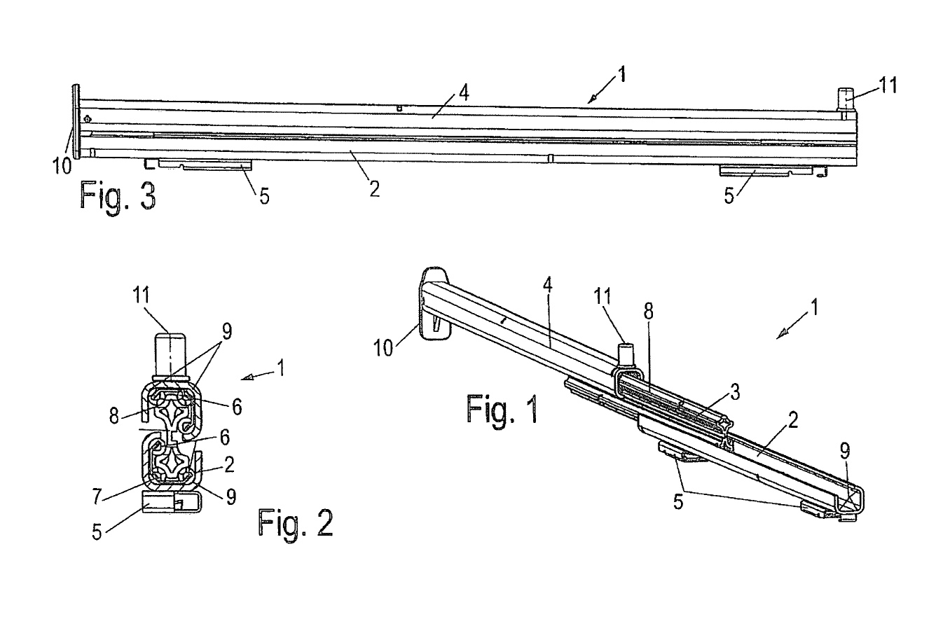

The pull-out guide 1 includes a guide rail 2 which can be fixed to a side grating in an oven, a side wall of an oven or a furniture body. A middle rail 3 is displaceably held on the guide rail 2 via roller elements 6. The middle rail 3 is used for bearing a running rail 4. At least two tracks 9, or, for example, three tracks 9 as suggested in FIG. 2, for roller elements 6 are arranged on the guide rail 2 and the running rail 4 for bearing the rails 2, 3 and 4. The roller elements 6 are held as a unit in the roller element cage 7. A total of at least four tracks 9, as suggested in FIG. 1 for roller elements 6, are further arranged in the middle rail 3, with at least two tracks 8 being associated with the guide rail 2 and at least two tracks 8 being associated with the running rail 4.

Two clamps 5 are fixed to the guide rail 2 for fixing the pull-out guide 1 to a side grating of an oven. Other fastening means or fastening points can, within the scope of the present disclosure, be provided on the guide rail 2.

The pull-out guide 1 is provided with a hard-material-containing ceramic coating, in accordance with the present disclosure, for example, on an externally accessible area, that is, on the outside of the guide rail 2 and the running rail 4. A plug 10, which is fixed to the running rail 4, is also coated on its externally accessible areas with a hard-material-containing ceramic coating, for example. A holding bolt 11 is also provided with this coating, for example. The inside of the running rail 4 and the guide rail 2, on which the tracks 9 for the roller element 6 are arranged, does not, for example, have any coating. The middle rail 3, which is completely arranged in the interior region of the pull-out guide 1 when the running rail 4 is arranged in the retracted position, is also, for example, not provided with any coating, at least in the region of the tracks 8. Consequently, the tracks 8 can be formed by the material of the rails 2, 3 and 4. The tracks 8 and 9 will be made of a bent steel sheet for the most part, however. A high level of scratch resistance and temperature strength of the surface is achieved on the outside by a hard-material-containing ceramic coating on the rails 2 and 4, so that foodstuff racks can be arranged on the pull-out guide 1, for example. The pull-out guide 1 can, therefore, be used in an oven especially well, with a high level of running quality being achieved over a long period of life. FIGS. 1 to 3 show an overextension runner, or pull-out guide 1, with three rails 2, 3 and 4. An embodiment with at least three rails as a full-extension runner is within the scope of the present disclosure. It is also within the scope of the present disclosure to arrange the pull-out guide 1 as a partial-extension runner with only two rails, that is, for example, without the middle rail 3, or with more than three rails.

Wood, glass and polymers, and, for example, ceramics and metals, are considered as components of the composites, in accordance with the present disclosure, which are processed into layer and particle composites in conjunction with hard-material layers or hard-material particles. Hard metals and ceramics belong to the particle composites, for example. Fiber composites are also generally included in the composites for coating the metal component, in accordance with the present disclosure.

Other than hard-material coatings, as are known from the state of the art, composites can be applied at lower temperatures to the surface of the metal component. It is sufficient in thermal coating methods to liquefy the low-melting fractions of the composite matrix, whereas the mostly higher-melting hard-material components are already entrained by the liquid composite matrix and are thereafter embedded in the coating.

The hard materials contained in the coating materials are materials which, as a result of their specific bonding character, have a Vickers hardness of more than 1000 HV10, where 1000=hardness value, HV=method and 10=testing force in kilopond, and which Vickers hardness may be more than 3000 HV10. The melting point of hard materials is mostly over 2000° C. In addition to corundum, hard materials are, for example, also carbide, nitride, boride and silicide compounds. The most important representatives of the class of hard materials are diamond, cubic crystalline boron nitride, silicon carbide, aluminum oxide, boron carbide, tungsten carbide, vanadium carbide, titanium carbide, titanium nitride, and zirconium dioxide.

The composite can alternatively or additionally, be formed on the basis of a ceramic-metal composite, or cermet. Cermet is a designation that is translated as a metal-ceramic for a group of materials consisting of two separate phases, with a metallic and a ceramic component which differ from one another in respect of hardness and melting point. An increase in the ceramic fraction leads to an increase in the hardness, the melting point, thermal stability and scaling resistance. The metal fraction, on the other hand, improves thermal fatigue resistance, toughness and impact resistance of the metal component.

The pull-out guide 1, according to the present disclosure, includes an embodiment, for example, for use in ovens, a coating made of a hard-metal-containing composite which contains a high-temperature material. This metal component, in form of a fitting, can be used at temperatures over 500° C., that is, at temperatures which prevail in an oven with a pyrolysis operation, in which fittings without a coating in accordance with the present disclosure, partly tend towards scaling.

According to embodiments of the present disclosure, high temperature materials include Al₂O₃, BeO, CaO, MgO, SiO₂, ThO₂, or ZrO₂, and carbon materials, for example, coal or graphite. The latter two offer low thermal expansion in combination with high thermal conductivity and excellent thermal fatigue resistance at the same time. Furthermore, carbides, nitrides and aluminides such as HfC, TaC, ZrC, SiC, beryllium, boron, aluminum and silicon nitrides, and aluminides of the metals of nickel and iron can be used as high-temperature materials.

In an embodiment according to the present disclosure, especially for the use in ovens, the pull-out guide 1 comprises a coating made of hard-metal-containing composite with at least one ceramic material, especially a high-performance ceramic.

This ceramic material, according to the present disclosure, has a volume fraction of more than 30% of crystalline materials. The high-performance ceramic material comprises ultrapure oxides, nitrides, carbides and borides of precisely defined composition, particle shape and particle size distribution, and is processed as a powder by pressing and sintering into compact bodies, with optimal microstructure adjustment being taken into account. The average particle size of the hard materials can lie between 0.01 to 200 μm, or, for example, between 0.1 to 20 μm. The properties of the coating of the metal component when using a high-performance ceramic material depend more strongly on the structure than in metal materials.

The hard-material-containing high-performance ceramic materials may, for example, contain aluminum oxide, or corundum, Al₂O₃, zirconium dioxide, ZrO₂, silicon nitride, Si₃N₄, aluminum nitride, AlN, silicon carbide, SiC, boron carbide, B₄C, and titanium diboride, TiB₂.

Fittings with a coating layer on the basis of a high-performance ceramic material are high-temperature resistant, corrosion-proof and wear-resistant. They offer pressure resistance, hardness and creep resistance as well as favorable sliding properties in combination with high thermal and chemical resistance. In addition, they can assume electrical, magnetic, optical and biological functions.

According to the present disclosure, the high-performance ceramic material can be mixed with hard materials as a powder composition and can be applied in a powder coating method to the surface of the metal component. This ensures a defined grain size distribution and a defined coating surface. The coating produced in this manner shows a high packing density of the powder particles in the coating, leading to a high sintering density in combination with the lowest possible shrinkage. Slip-cast coatings with high-performance ceramic materials can also show higher packing density and therefore narrower pore size distribution in comparison with cold-pressed bodies.

According to the present disclosure, high sintering temperatures and/or high external pressures are necessary for advantageously setting the structure in the hard-material-containing coating with a predominant fraction of high-performance ceramics, especially in order to accelerate the grain-boundary diffusion-controlled material transport under reduced liquid-phase fraction in Si₃N₄ and AlN ceramics. In order to prevent the decomposition of Si₃N₄ at sintering temperatures of more than 1800° C., gas pressure sintering with an N₂ pressure of 1 to 10 MPa is applied, which enables sintering temperatures of over 2000° C. The anisotropic grain growth can, thereby, be utilized in a purposeful manner and a structure of low intergranulary glass fraction but high degree of extension of the crystallization can be produced. The fracture toughness and the high-temperature resistance of the coating are additionally improved in this way.

According to the present disclosure, high-temperature isostatic pressing methods can also be applied to encapsulated or pre-sintered hard-material-containing ceramic composites. This occurs at gas pressures of up to 200 MPa under Ar, N₂ and O₂ atmosphere at temperatures of up to 2000° C. in order to advantageously enable a complete compaction of the hard-material-containing composite ceramics. The combination of pressureless sintering, gas-pressure sintering and high-temperature isostatic pressing in a compaction process, optimized for the respective material, allows producing a more homogeneous structure with low grain growth, smaller error size and higher density in hard-material-containing composites made of oxide and non-oxide ceramic materials.

According to the present disclosure, hard-metal-containing composites with novel structures and properties can be produced by chemical reaction processes. It is also within the scope of the present disclosure to use autocatalytic reaction processes, Al₂O₃/B₄C, displacement reactions, Al₂O₃/TiN, and eutectic crystallization, Al₂O₃/ZrO₂, reactions of organometallic compounds as SiC/SiO₂, polymer reaction techniques Si₃N₃/SiC, melting-phase filtration techniques Si/SiC, directional melt oxidation Al₂O₃/Al, and gas-phase filtration/deposition BN, SiC/SiC.

The reaction processes according to the present disclosure, offer advantages for the coating of a metal component over conventional processes because, on the basis of pure starting substances, they enable easy shaping of the coating, low shrinkage and high dimensional stability, and a reduction in the structural stresses in hard-material-containing composites.

The hard-material particles of the composite are made of corundum in an embodiment according to the present disclosure, with the composite of the coating additionally being strengthened by fibers, for example, alpha-aluminum oxide fibers. The composite is advantageously resistant to thermal shocks, scratch-proof and resistant to temperatures of up to 800° C. The coating adheres to the component surface, with material tensions occurring in only a small area between the component and the coating. Such coated fittings can be used in ovens with pyrolysis operation, according to the present disclosure.

When advantageously using corundum as a hard material in accordance with the present disclosure, this material is pulverized and ground with a mass fraction of 8 to 25% of a bonding agent made of clay, quartz or a polymer, applied in a humidified condition by a spraying or extrusion process to the metal component, for example, the fitting, and baked at 1300 to 1400° C. The individual components will sinter into a uniform hard composite.

Alpha-aluminum oxide fibers, or saphibres, can be added to the corundum-bonding agent compound as an advantageous embodiment, according to the present disclosure, of a hard-material-containing composite, and subsequently the compound can be applied by extrusion coating to the surface of the component.

Alternatively, in accordance with an embodiment of the present disclosure, a magnesium oxide, MgO, ceramic can be a component of the hard-material-containing composite which was mixed with hard-material particles. Magnesium oxide ceramic is a material sintered from magnesium oxide, or periclase, or magnesium aluminate, or spinel. The melting point of such a coating lies over 1500° C., so that a metal component coated in this manner can be used as a fitting itself in sintering furnaces and the like.

Although relatively high vapor pressures are necessary for densifying this coating into a ceramic material, such a coated fitting is suitable for special applications in the refractory industry, for example, in muffle furnaces, or in the field of metallurgy. The MgO-based embodiment of the coated fitting shows very high corrosion resistance, especially in the alkaline environment. Magnesium oxide can also be used in other ceramic materials as a coating material, for example, in Al₂O₃ ceramics, in order to advantageously obstruct the grain growth there during sintering.

In a further embodiment according to the present disclosure, the coating comprises a ceramic composite with zirconium oxide.

A composite according to the present disclosure, can further comprise metallic nitrides as hard materials. Nitrides of the transition metals such as VN, CrN, W₂N are used in which the nitrogen atoms occupy the cavities in the metal structure and which show metallic character in respect of appearance, hardness and electrical conductivity. In addition to the hardness, the metallic appearance of the metal component is maintained, despite the coating. A composite with nitrides as the hard material can be produced, according to the present disclosure, in that nitrogen is introduced into a chromium steel melt under N₂ pressure up to a mass fraction of 1.8% under formation of iron nitride hard materials, and a metal composite is produced thereby with the metal matrix with a higher strength in comparison with conventional chromium steel.

Covalent nitrides, which are considered as hard materials for the composite, are mainly formed with elements of the 13^{th} group such as BN, AlN, InN, GaN and Si₃N₄. The hard-material-containing composite which is produced therefrom is chemically resistant.

The nitrides, which may, according to the present disclosure, be as the hard-material component in the composite of the coating, are preferably produced by solid-state reaction, for example, by nitrifying metals with nitrogen, by conversion of metal oxides with ammonia in the presence of carbon, or by deposition from the gas phase, or CVD process, with a vapor mixture of metal halogenide, nitrogen and hydrogen being guided over a superheated tungsten wire.

In an embodiment according to the present disclosure, the coating of the metal component comprises aluminum nitride as the hard-material component. This hard material offers very good thermal conductivity and strength in combination with low thermal expansion and can be used in an advantageous way in ceramic coatings in conjunction with silicon and boron nitride.

Carbides can be used as the hard-material component in a composite in an embodiment according to the present disclosure.

Covalent carbides and metallic carbides are advantageous, according to the present disclosure, as the hard materials. They comprise compounds of the carbon with non-metals, the binding partner of which is less electronegative than carbon, such as, for example, boron carbide, silicon carbide and non-stoichiometric compounds of transition metals with carbon with the characteristic of an alloy. They are resistant to acids. The relatively small carbon atoms are located in the gaps of the metal lattice.

The formation of carbide on the surface of a metal component or fitting component, according to the present disclosure, can occur by reaction of elementary carbon or gases emitting carbon with the metallic surface of the metallic starting materials prior to shaping at 1200 to 2300° C. This carburetion may, for example, be performed under protective gas or in vacuum. Similarly, carbide layers or local crystallization focus areas of iron carbide species, such as cementite, can be formed in the carburization of steel on the surface of a component. A polymer layer or, —for example, a ceramic material or a passivating metal layer, can additionally be applied thereon, with the carbide fractions diffusing from the metal surface of the component into the layer disposed above the same and thereby forming a hard, screw-proof, deformable and flexible hard-material-containing composite coating.

Boron carbide or silicon carbide can be used, in an embodiment of the present disclosure, as hard-material particles in the coating of a metal component or fitting component.

Hard materials to be considered for the composite, in accordance with the present disclosure, also include borides as non-stoichiometric compounds of boron and a metal, which can be produced by powder metallurgy or by reaction of the metal oxides with boron carbide.

Boronizing the metallic surface of a metal component is within the scope of the present disclosure. The formation of an iron boride surface layer occurs by using iron-containing metal, which iron boride surface is very brittle and is insufficiently resistant to corrosion. Subsequently, a metal or ceramic coating is applied over this hard, scratch-proof hard-material layer. These layers connect by subsequent sintering into a water-repellent, corrosion-resistant composite. Titanium diboride is advantageous, according to the present disclosure, when used as boride hard material in the coating.

In a further embodiment in accordance with the present disclosure, the composite can consist mainly of ceramic-metal composite, or cermet.

For producing the cermet in accordance with the present disclosure, a ceramic powder composition is mixed with metal powders, the mixture is pressed under high pressure into a formed body and is sintered under neutral or weak acidic reducing atmosphere, the product is ground and applied, advantageously, by flame-spraying, for example, especially high-temperature flame-spraying, under pressure to the metal component to be protected, for example, a fitting.

Fiber-reinforced hard-material-containing materials are advantageous, according to the present disclosure, for coating a metal component, such as a fitting, whose surface is subjected to high mechanical loads. Pull-out guides, for example, pull-out guide 1, on which a foodstuff rack is disposed are subjected to such loads in the area of ovens, for example. The foodstuff racks can slide with friction at a number of places, especially during the extension and retraction of the cooking item on the surface of the pull-out guide 1. It may occur that a high abrasion force acts at certain points on the surface of the pull-out guide 1 and the coating applied thereto.

The hard-material-containing composite coating can, in accordance with the present disclosure, advantageously be fiber-reinforced for the purpose of better distribution of forces under point-like loads. So-called biomorphous ceramic materials, on the basis of cellulose-containing starting materials, are likewise advantageous. The starting materials for the fibers can be natural wood or wood-based materials. Natural wood is characterized by its mechanically efficient plant fiber designs. The process of liquid siliconization, or LSI process, can be used for producing SiC ceramics of wood or wood-based materials for coating fittings. For this purpose, the wood-based material is pyrolized in a first step under inert gas conditions. The obtained cellular or porous carbon formed body, or C-template, is subsequently infiltrated with liquid silicon. Silicon reacts with the carbon to form silicon carbide. Depending on the starting material and the process control, it is within the scope of the present disclosure to produce dense or porous SiC ceramics which show very different microstructures and therefore also very different properties as a result of the variable structural configuration.

In an advantageous embodiment of a method for applying the hard-material-containing composite or the ceramic-metal composite, in accordance with the present disclosure, chemical vapor deposition can occur by vaporizing, sputtering, ion plating, thermal-chemical vapor deposition, plasma-activated chemical vapor deposition, photon-active chemical vapor deposition, or laser-induced chemical vapor deposition.

Electrodeposition, in accordance with the present disclosure, can occur as a deposition variant of the hard-material-containing composite or the ceramic-metal composite by cathodic deposition, anodic deposition or electrophoresis.

The application of the hard-metal-containing composite by chemical deposition, in accordance with the present disclosure, occurs by electroless deposition, substitution reaction, homogeneous precipitation, spray pyrolysis, chromalizing, phosphatizing, nitriding, carboning or boriding.

An embodiment, accordance with the present disclosure, for applying a coating with a hard-material-containing composite occurs as a thermal injection process by flame-spraying, detonation spraying, arc spraying, plasma spraying or plasma spraying under vacuum, or by deposition welding, for example, as flame welding, arc welding, heating effect of current, plasma welding, plasma powder welding, plasma metal welding with inert gas, plasma hot-wire welding or laser beam welding.

A number of selected advantageous application methods, in accordance with the present disclosure, of the coating to the metal component or a component of a fitting is described below.

Coating by electrodeposition can occur in different ways. Cathodic deposition can occur by immersing the component into an aqueous electrolyte, a non-aqueous electrolyte, or a fused-salt electrolyte in which the hard-material particles are dissolved colloidally.

Alternatively, in accordance with the present disclosure, dispersion layers can also be applied by cathodic deposition onto the surfaces of the metal component or a fitting component. As a result, a metal layer with homogeneously distributed hard-material dispersions can be formed. In this application method, the hard-material particles are present at first in a dispersed dissolved manner in a metal ion solution. If the deposition of a metallic layer occurs on the surface of a metal component for a fitting, the dispersed dissolved hard-material particles will be deposited together with the metal layer and embedded in the layer.

The deposition by electrophoresis can occur, for example, by electro-dipcoating. This method, according to the present disclosure, allows the coating of conductive surfaces. A coating film will be deposited in a dipping bath consisting of an aqueous lacquer dispersion by the effect of electric direct current on the surface of the metal component dipped into the bath, for example, a fitting or fitting component. The item to be coated is switched as an anode. The lacquer dispersion, which contains ionically stabilized lacquer particles, will coagulate under current flow in the acidic boundary layer and form a coating film which adheres very well and which is hard and corrosion-proof after hardening at 120 to 200° C.

A hard-material-containing layer can, within the scope of the present disclosure, be formed by homogeneous precipitation. In this coating method, a deposit will be deposited on the surface of the metal component, for example, the fitting. This deposit can then be subsequently additionally condensed by thermal treatment or radiation.

Alternatively, in accordance with the present disclosure, the application of the hard-material-containing layer can occur as a liquid dispersion or solution by spray pyrolysis. In this process, the liquid dispersion or the liquid solution is broken down into micro droplets by an atomizer, which droplets reach the surface of the metal component. The component is heated in this process. In the case of aqueous dispersions or solutions, the temperature of the component is at least 95° C. Once the micro droplets reach the surface of the component, they will dry suddenly as a result of the increased temperature of the surface and will optionally be pyrolyzed at higher temperatures of over 500° C. Dispersed hard-material particles will be deposited on the surface, with a ceramic matrix forming from the dissolved fractions of the solution in which these hard-material particles are embedded. Alternatively, in accordance with the present disclosure, the hard materials in the ceramic layer can only form during pyrolysis as a result of reactions, like the ceramic layer.

The hard-material-containing composite layer can be applied in a chromating process to the surface of the metal component, for example, the fitting or the fitting component, in that a composite with a high fraction of chromium, for example, with a mass fraction of at least 20%, is applied to the surface. As a result of the chromium fraction, a passivating layer will form which is especially scratch-proof and hard as a result of the additional hard-material content. Chromating can occur by black chromium plating, hard chrome plating and especially preferably by bright chrome plating, as a result of which a metallic appearance of the coated component will additionally be achieved.

Alternatively, in accordance with the present disclosure, the formation of a hard-material-containing coating can occur by the treatment of a metal component, such as a fitting made of steel or cast iron, in such a way that the component is wetted with an alkali phosphate solution which comprises colloidally dissolved hard-material particles. This leads to the formation of a coating of a composite made of insoluble iron phosphates as a conversion layer which comprises inclusions of hard-material particles. They provide the conversion layer with an increased degree of hardness. These conversion layers provide briefly effective corrosion protection and at least allow the transport of the fitting over several months by overseas shipping under a salt-laden atmosphere and under brief contact with aggressive seawater. However, for the purpose of improving corrosion protection, it is recommended to provide the conversion layer additionally with polymers or especially with a ceramic or metallic layer, with the microporous surface of the additional layer offering a better adhesion base than would be the case by conventional abrasive treatment.

In accordance with the present disclosure, an abrasive treatment of the metal phosphate conversion layer, as a kind of hard-metal layer, can further increase adhesion of the additional layer in addition to the microporous surface. As a result, abrasive treatment can advantageously occur in such a way that roughening of the conversion layer is performed by preventing complete removal of the phosphate-containing hard-metal layer.

Alternatively, in accordance with the present disclosure, the formation of a hard-material-containing composite coating on the metal component can occur in such a way that a hard metal is formed by nitrifying which is simultaneously embedded in a composite.

In an embodiment according to the present disclosure, a hard-material-containing composite coating is applied, in that a multi-step process sequence is observed. On the basis of a metal component, for example, made of steel or cast iron, the introduction of nitride hard-material particles into the metal matrix occurs by the so-called salt-bath nitriding, or tenifer, method. Nitrogen and partly carbon will diffuse inwardly into the component surface in a salt melt made of potassium cyanide salt at approximately 580° C. A hard-metal layer with a layer thickness of approximately 10 to 30 μm is formed by this process. Salt-bath technology is characterized by short treatment periods, narrow temperature tolerances and reproducible quality standards.

Metal nitrides are formed by contact of the metal surface with the cyanide salt melt. These metal nitrides, which may, for example, be iron nitrides, can be defined as hard materials. As a result, the contact of the metal surface with the cyanide-containing solution leads to the formation of metal nitride hard materials in a metal matrix as a variant of a hard-material-containing composite as a hard metal, in accordance with the present disclosure.

A hard-metal layer is a hard-material-containing composite layer, within the terms of the application, and not a hard-material coating, since a hard-material layer has a lower brittleness as a result of the ductility of the metal matrix than a pure hard-material coating.

The metal-nitride-containing hard-metal layer can, in accordance with the present disclosure, additionally be provided with a further layer made of a ceramic material for improving the hardness of the composite coating, which further layer bonds with the hard-metal layer into a harder hard-material-containing composite. The bonding of both layers can be supported by a sintering method.

For the purpose of improved adherence of the additional layer on the hard-metal coating, an additional abrasive surface treatment of the hard-metal coating is recommended prior to the application of the further additional layer made of ceramic material, by means of which the diffusion into each other of the two layers by forming a new hard-material-containing composite is additionally improved, in accordance with the present disclosure.

Such a formation of a hard-material-containing composite is advantageous, in accordance with the present disclosure, because the hard materials are formed by reaction with a nitrogen-containing co-reactant directly on the surface of the metal component and will therefore adhere better to the metallic surface than foreign substances which are applied additionally to the component. In addition to cyanide compounds, other nitride-forming nitrogen compounds such as ammonia can be considered as co-reactants, in accordance with the present disclosure.

In an embodiment according to the present disclosure, a metal component is subjected to an ammonia atmosphere, wherein the formation of a metal-nitride hard-material coating occurs, which is followed by the coating with an organic or inorganic material by forming a hard-material-containing composite.

In an embodiment according to the present disclosure, a metal-nitride hard-material coating is formed by plasma-nitriding and is subsequently provided with a ceramic layer for example. The nitriding method is performed in a vacuum furnace at approximately 400° C. to 600° C. by using an ionized gas. Plasma-nitriding runs in the region of the metastable form of a glow discharge. For this purpose, the treatment gas is converted by a high voltage, for example, 600 V to 1000 V, and under negative pressure from a non-conductive gas to a partly ionized, electrically conductive plasma.

If individual areas of the metal component are not to be included in plasma-nitriding, for example, the tracks 8 of the previously described pull-out guide 1, these areas can be coated with a copper paste, in accordance with the present disclosure.

In addition to the use of nitrides as hard-material components in the composite, mixed compounds, consisting of carbon and nitrogen metal species can also be used as hard materials, in accordance with the present disclosure.

A mixed compound, according to the present disclosure, consisting of metal carbides and metal nitrides, can be embedded in the metal matrix of the surface of the metal component by a carbonitriding method at temperatures of between 700° C. and 1000° C., and a hard-metal component can be formed in this manner. An additional layer is subsequently applied to the surface, for example, one consisting of ceramic, thus leading to the formation of a new hard-material-containing composite combination. The composite thus produced contains metal carbides and metal nitrides and is mainly arranged as a ceramic coating.

A hardening method, in accordance with the present disclosure, of boronizing also leads to the formation of a hard-material coating, wherein elementary boron in form of powder or paste is applied to the metal component and is subsequently heated to a temperature of 800° C. to 1000° C. After the formation of the boride-containing hard-metal layer of iron borides, for example, the application and, for example, the subsequent sintering of an additional layer of ceramic for example will occur.

The application of a hard-material-containing composite can further occur by thermal spray methods, in accordance with the present disclosure.

The composition of the coating of the composite will be prepared, accordingly, prior to application and subsequently applied to the surface of the component by flame spraying, for example, high-speed flame spraying, detonation spraying, arc spraying, plasma spraying or plasma spraying in vacuum, in accordance with the present disclosure.

As an alternative to the previously prepared mixture of hard materials with inorganic or organic materials, in accordance with the present disclosure, the respective hard materials can alternatively also only be formed during the thermal spraying, for example, by oxidation reactions.

In a further application method according to the present disclosure, the composite mixture is applied by application welding to the surface of the component. This can be realized, among other ways, by flame welding, arc welding, heating effect of current, plasma welding, plasma powder welding, plasma metal welding with inert gas, plasma hot-wire welding or laser beam welding.

In the case of arc welding, arc welding can be applied with tungsten inert gas or TIG, metal inert gas, or MIG, metal active gas, or MAG, and submerged arc, or SAW.

The application by heating effect of current can be applied by electroslags, in accordance with the present disclosure.

In a further embodiment according to the present disclosure, the hard-material-containing composite coating can be applied to the metal component of a fitting by physical or chemical gas-phase deposition.

In the case of physical gas-phase deposition, the application, according to the present disclosure, can occur by vaporizing, sputtering, for example, with a diode system, ion beam system, triode system or magnetron system.

In a further embodiment according to the present disclosure, the application of the composite coating occurs by stationary glow discharge, such as DC glow discharge, by high-frequency glow discharge, by magnetron glow discharge, by hollow-cathode arc discharge, by ion cluster beam and by thermal arc discharge.

Although the present disclosure has been described and illustrated in detail, it is to be clearly understood that this is done by way of illustration and example only and is not to be taken by way of limitation. The scope of the present disclosure is to be limited only by the terms of the appended claims.

We claim:

1. A metal component for one or more of a fitting, a piece of furniture and a household appliance, the metal component comprising:
a coating, at least in sections; and
the coating including one of a hardness-containing composite material and a ceramic-metal composite material.

2. The metal component according to claim 1, wherein the coating has a Vickers hardness of more than 300 HV10.

3. The metal component according to claim 1, wherein the melting point of the coating is higher than 300° C.

4. The metal component according to claim 1, wherein the composite material includes at least one of a hard material and one of a metal, ceramic, fiber and synthetic material.

5. The metal component according to claim 1, wherein the composite material has a mass fraction of over 50% of one or both of a metal and a ceramic.

6. The metal component according to claim 1, wherein the composite material includes a hard material, selected from a group consisting of carbides, nitrides, borides and silicides.

7. The metal component according to claim 1, wherein the composite material includes one or more of corundum, fluorapatite, silicon nitride and/or molybdenum silicide.

8. The metal component according to claim 1, wherein the composite material includes a lubricant.

9. A method of producing the metal component according to claim 1, the method steps comprising:
providing the metal component; and
applying the coating, at least in sections, by one of gas-phase deposition, chemical deposition, electrochemical deposition, thermal spraying, and welding.

10. A household appliance comprising the metal component according to claim 1, arranged one of in and on the household appliance.

11. A piece of furniture, comprising the metal component according to claim 1, arranged one of in and on the piece of furniture.

12. A fitting, comprising the metal component according to claim 1, arranged one of in and on the fitting.

13. The metal component according to claim 1, wherein the coating has a Vickers hardness of between 500 and 100 V10.

14. The metal component according to claim 1, wherein the coating has a Vickers hardness of between 600 and 750 V10.

15. The metal component according to claim 1, wherein the melting paint of the coating is between 400° C. and 900° C.

16. The metal component according to claim 1, wherein the melting paint of the coating is between 500° C. and 700° C.
